(19) United States
(12) Patent Application Publication
(10) Pub. No.: US 2014/0216521 A1
(43) Pub. Date: Aug. 7, 2014

(54) Solar Electrical Generator System

(71) Applicants: Ronald Lee Bracken, El Cajon, CA (US); Johannes Johansson, San Ramon, CA (US)

(72) Inventors: Ronald Lee Bracken, El Cajon, CA (US); Johannes Johansson, San Ramon, CA (US)

(21) Appl. No.: 14/098,431

(22) Filed: Dec. 5, 2013

Related U.S. Application Data
(60) Provisional application No. 61/734,835, filed on Dec. 7, 2012.

(51) Int. Cl. H01L 31/052

(52) U.S. Cl. CPC H01L 31/0527
USPC 136/246

(57) ABSTRACT

In one embodiment, a solar electrical generator system includes a housing having a top side that is substantially transparent to solar radiation, and plurality of panels each having a passive face having reflective material, and an active face having reflective material and one or more photovoltaic (PV) cells. The plurality of panels are mounted within the housing substantially transversely to the top side and parallel to one another, such that solar radiation entering the housing through the top side and impinging a passive face of one panel is at least partially reflected thereby onto an active face of a neighboring panel.

PRIORITY CLAIM

This application claims the benefit of provisional patent application Ser. No. 61/734,835, filed Dec. 7, 2012, the disclosure of which is hereby incorporated herein by reference in its entirety.

### TECHNICAL FIELD

The present disclosure relates generally to solar energy generators, particularly those using photovoltaics.

### BACKGROUND

The use of photovoltaic cells to convert the radiant energy of sunlight into electrical energy is well known in the art. Many photovoltaic cell systems are designed for permanent mounting on a roof or on structures that require complicated assembly and installation. Many such systems have solar cell panels that are placed next to each other in a near horizontal configuration, which results in most of the sunlight being wastefully reflected back to the sky.

### OVERVIEW

As described herein, a solar electrical generator system includes a housing having a top side that is substantially transparent to solar radiation, and plurality of panels each having a passive face having reflective material, and an active face having reflective material and one or more photovoltaic (PV) cells. The plurality of panels are mounted within the housing substantially transversely to the top side and parallel to one another, such that solar radiation entering the housing through the top side and impinging a passive face of one panel is at least partially reflected thereby onto an active face of a neighboring panel.

Also as described herein, a solar electrical generator system includes a housing having a top side that is substantially transparent to solar radiation, and a plurality of panels each having first and second opposite faces. Each face has reflective material and one or more photovoltaic (PV) cells. The plurality of panels are mounted within the housing substantially transversely to the top side and parallel to one another, such that solar radiation entering the housing through the top side and impinging a face of one panel is at least partially reflected thereby a face of a neighboring panel.

### BRIEF DESCRIPTION OF THE DRAWINGS

The accompanying drawings, which are incorporated into and constitute a part of this specification, illustrate one or more examples of embodiments and, together with the description of example embodiments, serve to explain the principles and implementations of the embodiments.

In the drawings:

FIG. 1 is a perspective diagram of a solar generator;

FIG. 1A shows box 102 fitted with wheels 122 to provide mobility;

FIG. 1B shows box 102 fitted with a pair of legs 124 along one edge;

FIG. 2 is a perspective view showing details of one of the panels 112;

FIG. 3 is a diagram showing details of a light cell;

FIGS. 4, 5 and 6 are respectively top, side and front views of a box 402 in accordance with certain embodiments;

FIG. 5A is a side cross-sectional view of box 402 in certain embodiments;

FIG. 6A is a front cross-sectional view of box 402 in accordance with certain embodiments; and

FIG. 7 is a perspective view illustrating panel removability.

### DESCRIPTION OF EXAMPLE EMBODIMENTS

Example embodiments are described herein in the context of a solar electrical generator system. Those of ordinary skill in the art will realize that the following description is illustrative only and is not intended to be in any way limiting. Other embodiments will readily suggest themselves to such skilled persons having the benefit of this disclosure. Reference will now be made in detail to implementations of the example embodiments as illustrated in the accompanying drawings. The same reference indicators will be used to the extent possible throughout the drawings and the following description to refer to the same or like items.

In the interest of clarity, not all of the routine features of the implementations described herein are shown and described. It will, of course, be appreciated that in the development of any such actual implementation, numerous implementation-specific decisions must be made in order to achieve the developer's specific goals, such as compliance with application- and business-related constraints, and that these specific goals will vary from one implementation to another and from one developer to another. Moreover, it will be appreciated that such a development effort might be complex and time-consuming, but would nevertheless be a routine undertaking of engineering for those of ordinary skill in the art having the benefit of this disclosure.

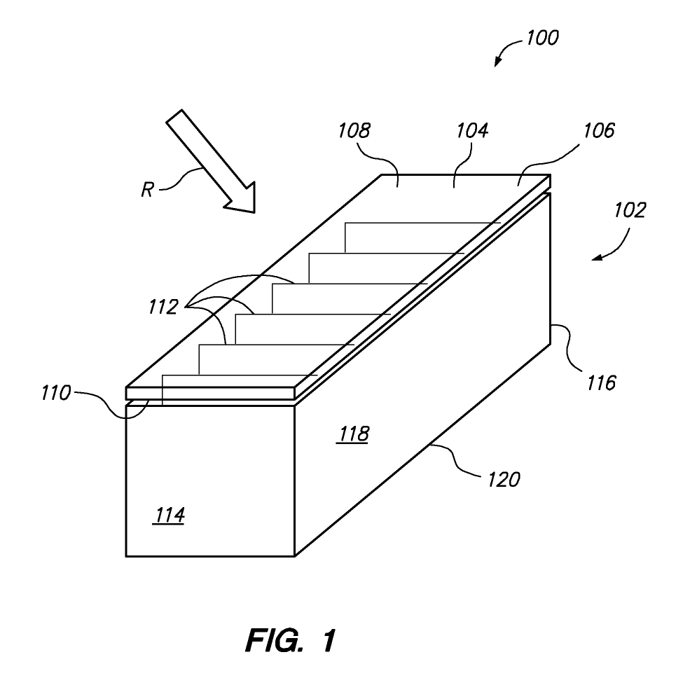

FIG. 1 is a perspective diagram of a solar generator 100, comprising a housing in the form of a generally rectangular box 102. Such a shape is by way of example only, as other shapes, such as trapezoidal, round, and so on, are also contemplated. The top 104 of box 102 may be open or uncovered, or it may comprise a clear or substantially transparent cover 106, for example made of glass or the like, to permit entry of solar radiation, depicted by arrow R. In certain embodiments, cover 106 is hinged or is otherwise displaceable to provide access to the interior 108 of the box 102. In certain embodiments, sides other than, or in addition to, top side 104, are displaceable for access to interior 108. In certain embodiments, sides other than, or in addition to, top side 104 are open or are transparent to solar radiation. An air gap 110, to permit ventilation of the interior 108, may be provided between the cover 106 and the remainder of the box 102, or between other sides and the remainder of the box. Other means of ventilation, such as holes, grills and other such as vents may be provided in different portions and different sides and bottom of the box 102 to thereby communicate air into and out of the box 102.

Within box 102, in interior 108, a row of panels 112 are disposed. In the exemplary box-shaped configuration, panels 112 are generally parallel to one another and to the front 114 and back 116 of the box, and are generally transverse to the sides 118, top 104 and bottom 120 of the box. The interior surfaces of the front 114, back 116, sides 118, and bottom 120, which define the interior 108 of the box 102, may be provided with reflective material, as detailed below. Furthermore, although not detailed herein, box 102 is configured to incorporate internal electrical wiring, switching, and connecters for the transmission of the produced electricity and its conveyance to an electrical storage system or to local electric utility company grid.

In certain embodiments, the panels are configured to be generally upright, in a substantially transverse relation to the top 104, so that an appreciable amount of solar radiation enters the box 102 and is reflected internally, by the backsides of neighboring panels, and by the internal walls and bottom of the box, as detailed below. In being substantially transverse to top 104, the panels can be perpendicular to the top, or at other, non-parallel angles with respect to the top.

FIG. 1A shows box 102 fitted with wheels 122 to provide mobility. FIG. 1B shows box 102 fitted with a pair of legs 124 along one edge, allowing the tilting of the box for better placement relative to the sun and improved capture of sunlight. The legs 124 may be hinged, telescopic or otherwise configurable to permit adjustment of the tilt of the box 102.

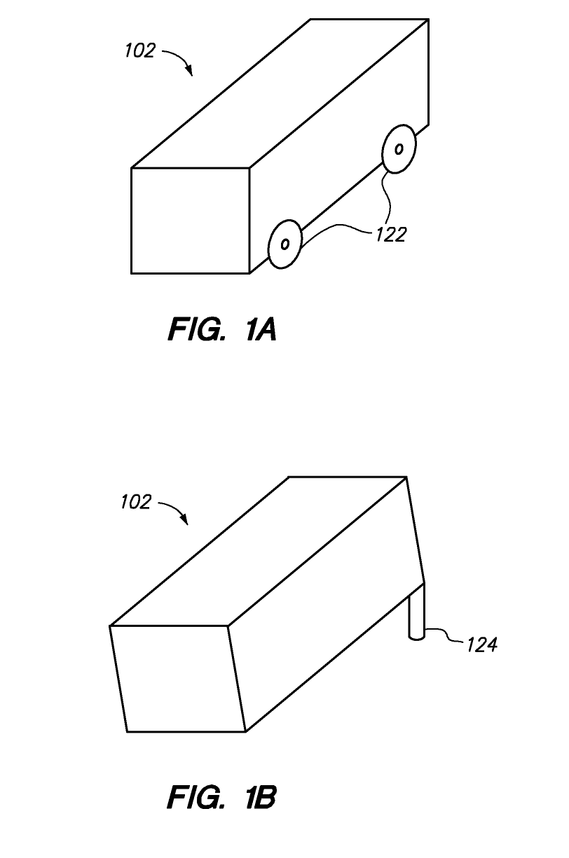

FIG. 2 is a perspective view showing details of one of the panels 112. A front, or active, face 202 of the panel supports an array of photovoltaic (PV) cells 204, four in this example. The PV cells 204 can be monocrystalline, polycrystalline (or Multicrystalline), Amorphous, PV cells from 3d printers, and spray-on PV such as solarwindow. Generally, any material that converts radiant energy to electricity can be used. Between the individual PV cells 204, inter-cell regions a, b, c and d, along with the border regions A, B, C, and D surrounding the cells, are provided with a reflective material for reflecting sunlight. The reflective material can be in the form of a coating or surface finish, for example having an RMS (root mean square) finish of about 0.4 um to about 0.012 um. The area of the reflective region will be a certain percentage of the total area of the active face 202. The remaining percentage of the active face area will be comprised of the area of the PV cells 204 of the active face 202. In certain embodiments, the percentage range of reflective region on the active face 202 will be about 2% to about 75%, with the remainder (about 98% to about 25%) being occupied by the PV cells 204.

The back, or passive, face 208 of the panel is also provided with a reflective material for reflecting sunlight onto the active face of the next panel in the row of panels. In certain embodiments, substantially all of the passive face will be reflective. In certain embodiments, back face 208 can also contain PV cells, so that both the front and back faces of each panel can be made active.

The inter-cell regions a, b, c and d, and the border regions A, B, C, and D, may all be collectively referred to herein as the active side reflector or reflective region, while back side 208 reflective region may be referred to as the passive side reflector or reflective region.

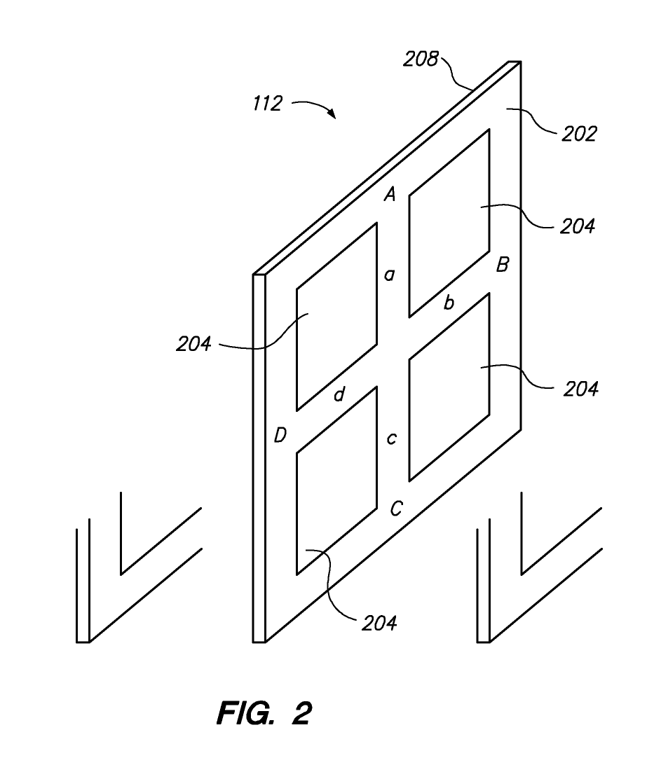

With reference to FIG. 3, a portion of the box 102, referred to as light cell 300, is described. More generally, the row of panels 112 form a plurality of such light cells each defined by the active face of one panel, the passive face of the next panel in the sequence, and portions of the interior surfaces of the sides 118 and bottom 120 between the active and passive faces. Light cell 300 in particular is defined by active face 302 of panel 312a, passive face 308 of panel 312b, side portions 318 (only one is shown), and bottom portion 320. As explained above in connection with FIG. 2, active face 302 includes an active-side reflector or reflective region comprised of the inter-cell regions a, b, c and d and the border regions A, B, C, and D. Similarly, passive face 308 includes a passive-side reflector or reflective region. Together, the active-side reflector, passive-side reflector, side portions 318 and bottom portion 320 of cell 300 provide a reflectance value that is a function of their total area.

The light cell reflectance value is one parameter that is taken into account in the design of the solar generator system. The inter-relation of the light cell reflectance value with other parameters of the solar generator system determines the performance characteristics of the system. Other parameters of interest are the inter-panel spacing—that is, the distance between the active-side reflector and the passive-side reflector of the cell—and the height and other dimensions of each cell. In FIG. 3, the inter-panel spacing is designated by the double-headed arrow s, and the height is designated by the double-headed arrow h.

In certain embodiments, the inter-panel spacing s is between about 0.5 inches and about 6.0 inches, depending on the height h. In certain embodiments, the height is in the range of about 9 inches to about 60 inches. In certain embodiments, the spacing s is about 0.75 inches, for a height h of about 9 inches. In certain embodiments, the spacing is about 1.75 inches, for a height of about 37 inches. In certain embodiments, the spacing does not exceed about 6 inches, and the height does not exceed 60 inches.

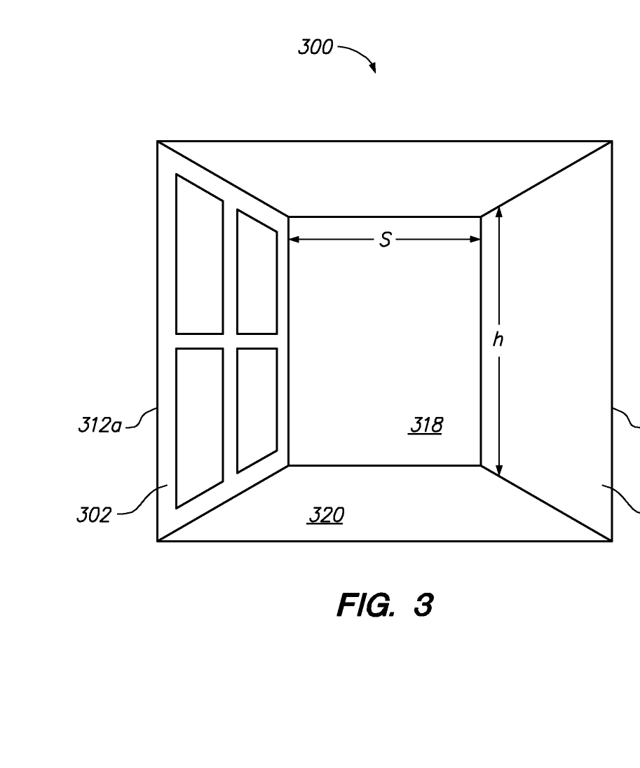

FIGS. 4, 5 and 6 are respectively top, side and front views of a box 402 in accordance with certain embodiments. It can be seen that box 402 can be provided with quick disconnect protrusions 403 so that multiple boxes can be arrayed together mechanically and electrically, in serial electrical connection. The protrusions 403 can be equipped with electrical connectors (not shown) for this purpose, along with fasteners such as screws and the like for the mechanical connection. Electrical cables (not shown) running along the length of the box 402, for example within the side walls, and terminating at the protrusions 403, make electrical connections with the individual panels 112 in the box, through for example the edge connectors described below.

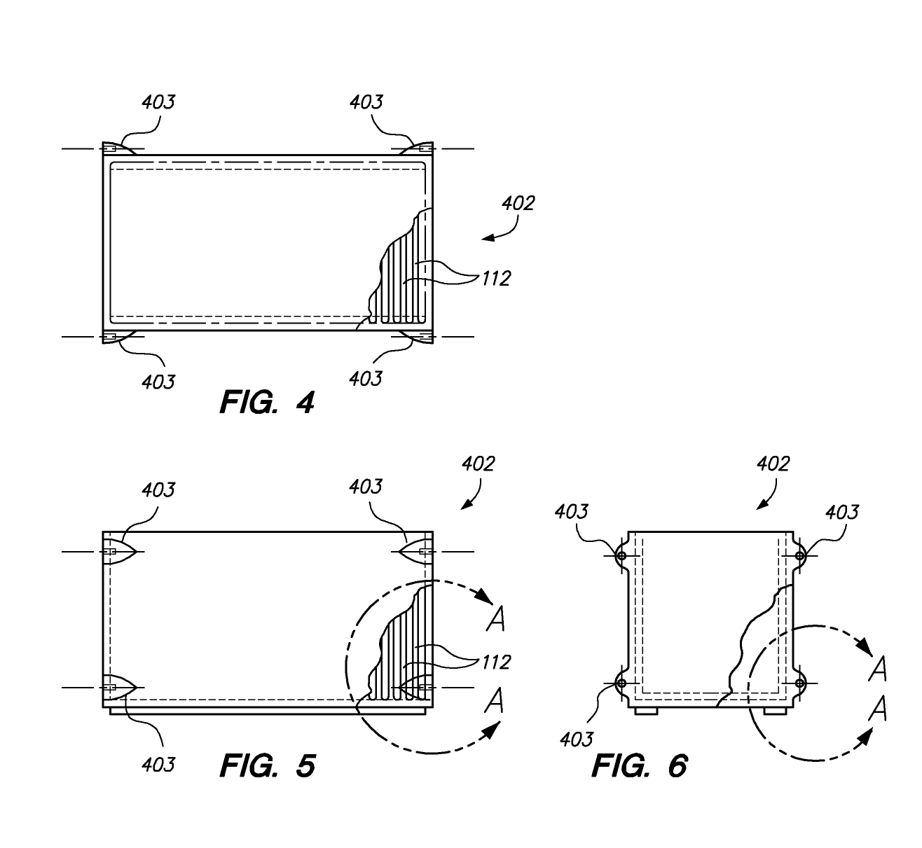

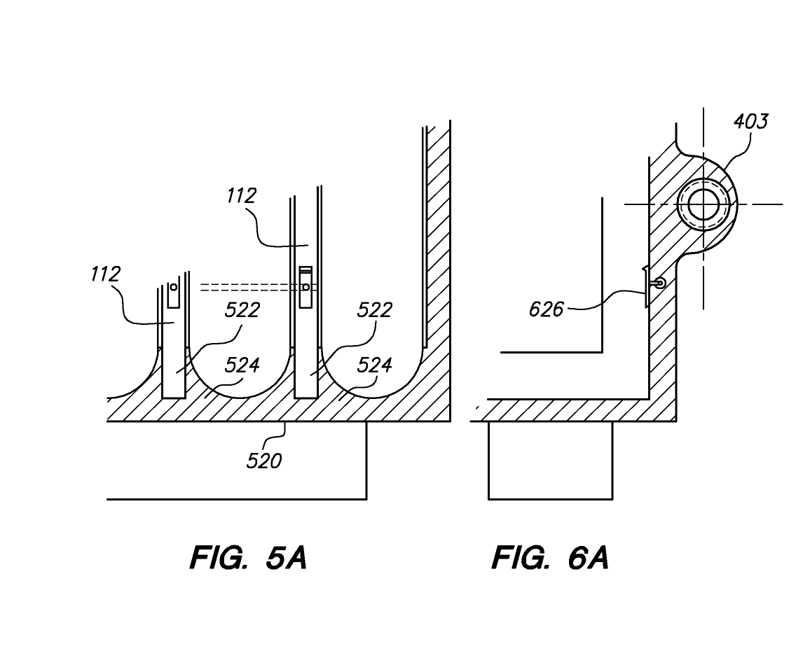

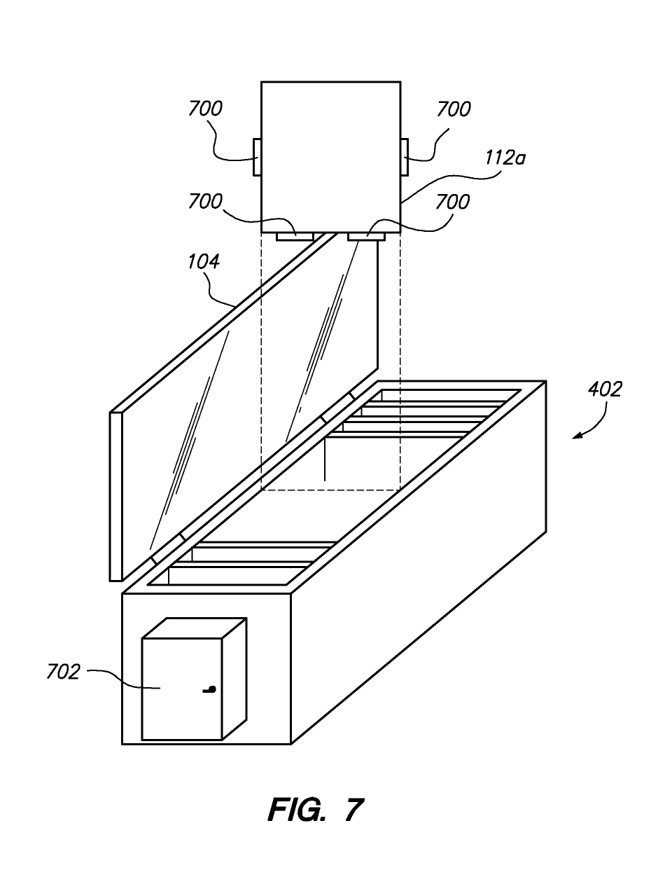

FIG. 5A is a side cross-sectional view of box 402 in accordance with certain embodiments. FIG. 6A is a front cross-sectional view of box 402 in accordance with certain embodiments. As seen, in certain embodiments, portions 524 of reflective bottom 520 are rounded (circular) or otherwise curved (parabolic, hyperbolic, elliptical, etc.) in shape, to enhance reflectivity of sunlight within the light cells, by eliminating dead corners that are inefficient reflectors. Moreover, grooves 522 can be provided to retain the panels 112 in place. Such rounded shapes and grooves can similarly be provided in the sides (not shown) of the box 402. In this manner, the panels 112 can be slid into place in the grooves in the sides and bottom, and can be removed therefrom for cleaning, maintenance or replacement. Other means, such as tabs, keys, spring edge connectors 626 (FIG. 6A) for making electrical and mechanical connection, and the like, or combinations thereof, can be provided to permit removability of the panels 112. This removability is illustrated by the dashed representation of panel 112a in FIG. 7. In certain embodiments, bottom and/or side edge connectors 700 can be provided in the panels for electrical contact with corresponding edge connectors (not shown) in the housing. Also shown in FIG. 7 is an optional compartment 702 to house some electrical components, such as inverters, regulators, and the like, to which the panels 112 may be connected.

The solar electric generator system described herein provides several advantages. These included reduced size, because by placing the cells vertically, the actual footprint can be reduced up to 95% compared to a conventional flat panel array. They also include the use of less costly material surrounding the PV cells than current systems, including fewer parts. Also, the box allows the PV cells to have less individual encapsulation than current flat panel systems. Materials used can include, by way of example, epoxy or similar, chrome spray paint to create mirrored surface or reflective material, Kevlar, off the shelf PV cells, injection mold.

Another advantage is that less manufacturing steps are required. For example, the system can be fabricated through mold waxing. In addition, shortened installation time is contemplated, with a “plug-and-play” stand alone modular design which can be placed almost anywhere. If unit is for residential use, then a cord can carry the electricity to the main power panel, to further be distributed to home or net meeting. Connection to a battery, for off the grid usage is also contemplated. Commercial (solar farm) use is also possible, wherein simply placing the unit(s) on the ground without support structures is possible, unlike conventional applications that require such support structures. Another advantage is in space saving—since the design reduces weight and size. In a military setting, a more portable electricity generator system is a possible application, and can be made sturdier to handle roughness.

Another advantage is allowing for do-it-yourself repair or upgrade without needing the help of a technician or company. Removing and replacing a PV panel by sliding panel out from vertical or side opening is a simple task. In certain embodiments, indicator lights or the like can be provided to show the health of the panel or system (different colors or a 1-100% scale), and could be an indicator of when panels needs to be replaced.

Further, the total system weight is lighter than current flat panel arrays systems. For example, instead of heavy tempered glass to protect the PV cell, the PV cells 204 of a panel can be covered in epoxy, which is lighter. Only the top side 104 for instance would need to be sturdier to protect cells from weather, precipitation, debris and the like. Further, as mentioned above, no mounting system, for example a heaving metal frame, would be needed to house the PV cells. The housing of the present design can be made robust using injection mold and Kevlar.

In addition, the generator produces a higher watt output than PV cells placed flat in low light conditions, due to the effects of the higher density of the vertical panels and the utilization of the reflection from the passive sides of the panels and the sides of the housing. This translates to more “sun hours” of close to maximal output per 24 hour cycle.

The arrangement described herein maximizes electricity production of photovoltaic cells per square area. By effectively trapping the light inside of a box, more light can be converted to electricity than if the PV cells are perpendicular (such as in flat panel arrays) to the sun. The light that enters the box's opening will reflect back and forth until a substantial amount of the photos are used up by the PV cells. This also allows the PV cells to perform close to maximal output even when the sun is not intensive, without having to track the suns movement, or adding additional moving parts. Throughout a 24 hour period, the generator generates more energy by measurement of watts output than a similar (watt) sized Photovoltaic system that uses the flat panel array formation.

In one embodiment, placement in a sunny location on the ground is contemplated. The unit can alternatively be placed on a roof or other constructed site. The generated electricity would be transferred via a power cable to either a house main electrical panel, or to a battery, or other devices. Even better results may be achieved by using a 5 degree tilt of the box towards south, using adjustable legs as described above. Fenders can also be added to reflect additional light into the box, for example when placed on the north-side (or back side) of the box.

While embodiments and applications have been shown and described, it would be apparent to those skilled in the art having the benefit of this disclosure that many more modifications than mentioned above are possible without departing from the inventive concepts disclosed herein. The invention, therefore, is not to be restricted except in the spirit of the appended claims.

What is claimed is:

1. A solar electrical generator system comprising:
a housing having a top side that is substantially transparent to solar radiation; and
a plurality of panels each having a passive face having reflective material, and an active face having reflective material and one or more photovoltaic (PV) cells, the plurality of panels mounted within the housing substantially transversely to the top side and parallel to one another, such that solar radiation entering the housing through the top side and impinging a passive face of one panel is at least partially reflected thereby onto an active face of a neighboring panel.

2. The system of claim 1, wherein the plurality of panels are spaced between about 0.5 inches and about 6 inches apart.

3. The system of claim 2, wherein the housing has a height in the range of about 9 inches to about 60 inches.

4. The system of claim 3, wherein reflective material occupies about 2% to about 75% of the active face area.

5. The system of claim 1, wherein the top side includes a displaceable cover.

6. The system of claim 1, wherein the housing includes one or more sides, and the top side is mounted in a spaced configuration from the one or more sides.

7. The system of claim 1, wherein the housing includes one or more sides that are provided with a reflective material.

8. The system of claim 1, wherein the housing provided with adjustable legs configured to impart a tilt to the housing.

9. The system of claim 1, wherein the housing is provided with one or more wheels to impart mobility to the housing.

10. The system of claim 1, wherein the housing contains one or more light cells each defined by a passive face of one panel, an active face of a neighboring panel, and opposite side portions and a bottom portion of the housing, and wherein at least one of said opposite side portions or bottom portion has a curved surface.

11. The system of claim 1, wherein the housing is provided with means for removably supporting the panels.

12. The system of claim 11, wherein the housing is provided with protrusions for electrically and/or mechanically coupling additional housings thereto.

13. A solar electrical generator system comprising:
a housing having a top side that is substantially transparent to solar radiation; and
a plurality of panels each having first and second opposite faces, each face having reflective material and one or more photovoltaic (PV) cells, the plurality of panels mounted within the housing substantially transversely to the top side and parallel to one another, such that solar radiation entering the housing through the top side and impinging a face of one panel is at least partially reflected thereby a face of a neighboring panel.

14. The system of claim 13, wherein the plurality of panels are spaced between about 0.5 inches and about 6 inches apart.

15. The system of claim 14, wherein the housing has a height in the range of about 9 inches to about 60 inches.

16. The system of claim 15, wherein reflective material occupies about 2% to about 75% of the area of each face.

17. The system of claim 13, wherein the top side includes a displaceable cover.

18. The system of claim 13, wherein the housing includes one or more sides, and the top side is mounted in a spaced configuration from the one or more sides.

19. The system of claim 13, wherein the housing includes one or more sides that are provided with a reflective material.

20. The system of claim 13, wherein the housing is provided with adjustable legs configured to impart a tilt to the housing.

21. The system of claim 13, wherein the housing is provided with one or more wheels to impart mobility to the housing.

22. The system of claim 13, wherein the housing contains one or more light cells each defined by a face of one panel, a face of a neighboring panel, and opposite side portions and a bottom portion of the housing, and wherein at least one of said opposite side portions or bottom portion has a curved surface.

23. The system of claim 13, wherein the housing is provided with means for removably supporting the panels.

24. The system of claim 23, wherein the housing is provided with protrusions for electrically and/or mechanically coupling additional housings thereto.

25. The system of claim 1, further comprising one or more vents for communicating air into and out of the housing.

26. The system of claim 13, further comprising one or more vents for communicating air into and out of the housing.
